(19) United States
(12) Patent Application Publication
(10) Pub. No.: US 2022/0291283 A1
(43) Pub. Date: Sep. 15, 2022

(54) AUTOMATIC CHIP TESTING SYSTEM AND METHOD

(71) Applicants: Inventec (Pudong) Technology Corporation, Shanghai (CN); INVENTEC CORPORATION, Taipei (TW)

(72) Inventor: Ye LIU, Shanghai (CN)

(73) Assignees: Inventec (Pudong) Technology Corporation, Shanghai (CN); INVENTEC CORPORATION, Taipei (TW)

(21) Appl. No.: 17/356,529

(22) Filed: Jun. 24, 2021

(30) Foreign Application Priority Data
Mar. 10, 2021 (CN) 2021102619459

(51) Int. Cl. G01R 31/3177; G06F 13/42

(52) U.S. Cl. CPC G01R 31/3177; G06F 13/4282; G06F 2213/0016

(57) ABSTRACT

The present disclosure provides an automatic chip testing system and method. The automatic chip testing system includes: a client, which is used to send a test instruction regarding the chip; a server, which includes a main board and a chip connected to it. The main board is used to receive the test instruction, convert the test instruction into a test file, and transmit the test file to the chip; the chip is used to trigger test items related to the test file after receiving the test file, the function test result of the chip is generated, and the function test result of the chip is shared to the client through the main board. The disclosure improves the reliability of the chip test result, and saves the test time.

### CROSS REFERENCE TO RELATED APPLICATION

The present application claims the benefit of priority to Chinese Patent Application No. CN 2021102619459, entitled “AUTOMATIC CHIP TESTING SYSTEM AND METHOD”, filed with CNIPA on Mar. 10, 2021, the disclosure of which is incorporated herein by reference in its entirety.

### FIELD OF TECHNOLOGY

The present disclosure generally relates to the technical field of chip testing, in particular to an automatic chip testing system and method.

### BACKGROUND

In a server system, chips occupy a very special position. Motherboard CPU, PCH, BMC and VRMS interact with chips more and more often, and the number of control modules inside chips is also rapidly increasing. Therefore, the testing of chip functions has become more and more complicated. The existing test method shown in FIG. 1 relies on an oscilloscope to measure signals sequentially. It requires a skilled engineer to understand the working mechanism of the corresponding system before the test can be performed. The existing method is not only a test for the test engineer; it also has a lengthy test cycle, and requires time-consuming and labor-intensive result inspection.

### SUMMARY

The present disclosure provides an automatic chip testing system and method. The automatic chip testing system includes: a client, which is used to send a test instruction regarding the chip; a server, which includes a main board and a chip connected to it. The main board is used to receive the test instruction, convert the test instruction into a test file, and transmit the test file to the chip; the chip is used to trigger test items related to the test file after receiving the test file, the function test result of the chip is generated, and the function test result of the chip is shared to the client through the main board.

The automatic chip testing system and method described in this application have the following beneficial effects:

First, this application can realize a uniform test mode, and eliminates the need for a test engineer to understand the system, and the test can be simply conducted by referring to the SOP which provides a clear testing process.

Second, this application has high portability, offers modular division of labor, and embeds test modules in working modules to reduce secondary development work;

Third, this application offers automatic and intelligent script testing;

Fourth, this application improves the reliability of test results and reduces human factors by 100%;

Fifth, this application saves test time and is easy to operate;

Sixth, this application has strong applicability and reduces training costs.

### BRIEF DESCRIPTION OF THE DRAWINGS

FIG. 1 shows a schematic diagram of an existing test method.

FIG. 2 is a structural diagram of an automatic chip testing system according to an embodiment of the present disclosure.

FIG. 3 is a flowchart showing an automatic chip testing process according to an embodiment of the present disclosure.

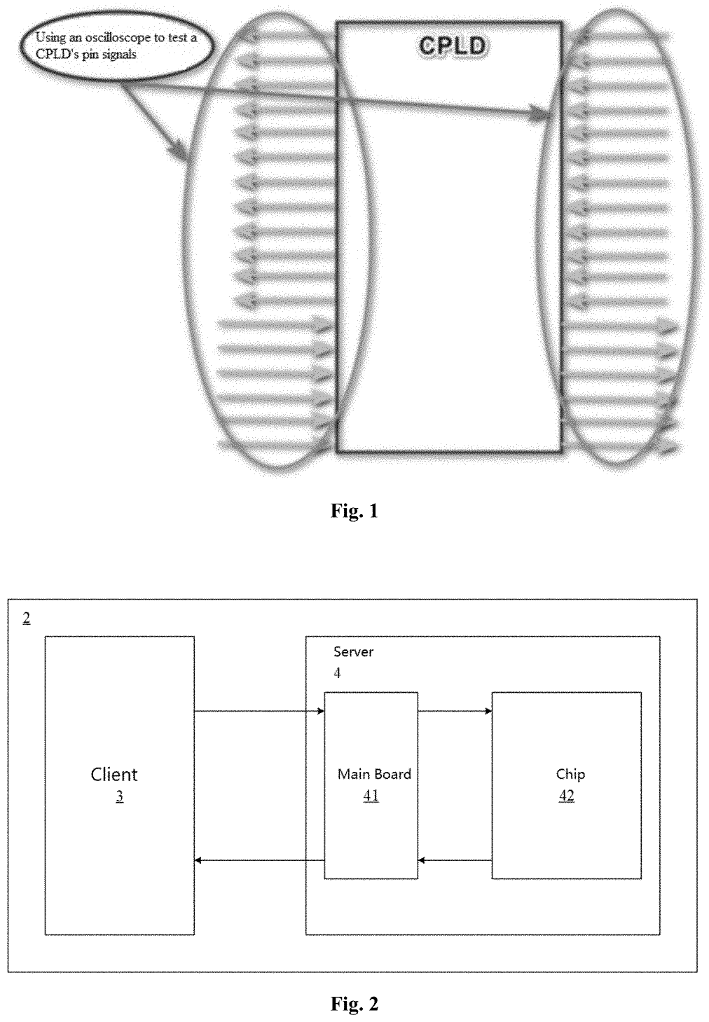

### DETAILED DESCRIPTION

One or more specific embodiments of the present disclosure will be described below. These described embodiments are only examples of the presently disclosed techniques, and are not intended to limit aspects of the presently disclosed disclosure. Additionally, in an effort to provide a concise description of these embodiments, all features of an actual implementation may not be described in the specification. It should be appreciated that in the development of any such actual implementation, numerous implementation-specific decisions must be made to achieve the developers' specific goals, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

### Embodiment 1

This embodiment provides an automatic chip testing system, including: a client, configured to send a test instruction regarding a chip; and a server, including a main board, and a chip connected to the main board.

The main board is configured to receive the test instruction, convert the test instruction into a test file, and transmit the test file to the chip. The chip is used to trigger a test item related to the test file after receiving the test file, generate a function test result of the chip, and send the function test result of the chip to the client through the main board.

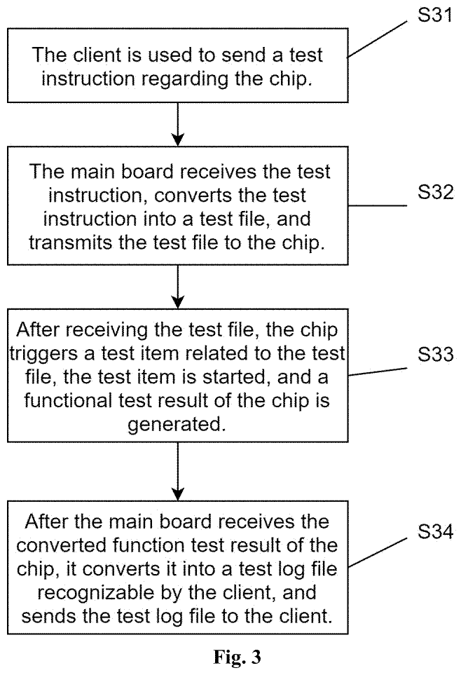

The automatic chip testing system provided by this embodiment will be described in detail below in conjunction with the drawings. Please refer to FIG. 2, which shows a structural diagram of the automatic chip testing system. As shown in FIG. 2, the automatic chip testing system 2 includes a client 3 and a server 4.

In this embodiment, the client 3 is used to send a test instruction regarding the chip.

In this embodiment, the client 3 includes an interface connection software for communicating with the server 4, for example, PuTTY (a connection program for Telnet, SSH, rlogin, pure TCP and serial interface).

In this embodiment, the client 3 sends the test instruction to a main board 41 of the server 4 through a Universal Asynchronous Receiver Transmitter (Share NIC) or a network interface controller (Share NIC).

Specifically, the test instruction includes a register instruction, and the format of the register instruction is address bit+register value.

Still referring to FIG. 2, the server 4 includes the main board 41 and a chip 42 communicatively connected with the main board 41. In practical applications, the chip 42 includes a complex programmable logic device (CPLD) and/or a field programmable gate array (FPGA).

In this embodiment, the main board 41 and the chip 42 perform intersystem data interaction according to one or more transmission protocols.

Specifically, modules of the main board such as a central processing unit (CPU), platform controller hub (PCH), integrated Southbridge, baseboard management controller (BMC), or voltage regulation module (VRMs) of the main board 41 performs data interaction with the chip 42.

The transmission protocols are chosen from the serial general purpose input/output (SGPI/O) protocol, the Low Pin Count (LPC) protocol, the Inter-Integrated Circuit (I2C, or I²C) protocol and the Serial Peripheral Interface (SPI) protocol.

The main board 41 is used to receive the test instruction, convert the test instruction into a test file, and transmit the test file to the chip 42.

Specifically, the main board 41 converts the test instruction into a test file in compliance with one or more of the SGPI/O protocol, the LPC protocol, the I2C protocol and the SPI protocol.

The chip 42 is used to trigger a test item related to the test file after receiving the test file, then the test item is started, and the function test result of the chip is generated, and the function test result is sent through the main board 41 to the client 2.

In this embodiment, the chip 42 is also used to convert the function test result of the chip into a test result in compliance with one or more of the SGPI/O protocol, the LPC protocol, the I2C protocol and the SPI protocol.

After the main board 41 receives the converted function test result of the chip, the main board 41 converts the latter into a test log file recognizable by the client 3, and sends the test log file to the client 3 by a Universal Asynchronous Receiver Transmitter or Network Interface Controller.

After receiving the test log file, the test engineer compares the test log file with a reference test SOP to determine whether the test result indicates a success or failure so as to save test time and improve the reliability of the test result.

The following is an example of testing using the automatic chip testing system described in this embodiment:

First, the client sends the power test command P5V fault command\textcircled{1} I2c b 0×05 w 0×47 0×e2.

Then, after the main board receives the power supply test command, the main board converts the power supply test command into a test file, that is, assert P5V power good, and sends it to the CPLD.

Then, the CPLD triggers corresponding test items according to the test file, the test event occurs, the test result is generated, that is, the system shuts down, and the test result is fed back to the main board.

Finally, the main board records the test log (i.e. System shut down by P5V\textcircled{2} power fault) and the event of system shutdown, then the test items can be completed and the test report can be filled in.

The automatic chip testing system described in this embodiment has the following beneficial effects:

First, this embodiment can realize a uniform test mode, and eliminates the need for a test engineer to understand the system, and the test can be simply conducted by referring to the SOP which provides a clear testing process.

Second, this embodiment has high portability, offers modular division of labor, and embeds test modules in working modules to reduce secondary development work;

Third, this embodiment offers automatic and intelligent script testing;

Fourth, this embodiment improves the reliability of test results and reduces human factors by 100%;

Fifth, this embodiment saves test time and is easy to operate;

Sixth, this embodiment has strong applicability and reduces training costs.

### Embodiment 2

This embodiment provides an automatic chip testing method applied in an automatic chip testing system. The automatic chip testing system includes a client and a server connected to the client, and the server includes a main board and a chip connected to the main board. The automatic chip testing method includes:

sending, by the client, a test instruction regarding the chip;

receiving, by the main board, the test instruction, converting, by the main board, the test instruction into a test file, and transmitting, by the main board, the test file to the chip;

after receiving the test file, triggering a test item related to the test file, by the chip, to generate a functional test result of the chip; and

sending the function test result of the chip to the client by the main board.

The automatic chip testing method provided in this embodiment will be described in detail below. Please refer to FIG. 3, which shows a flowchart of the automatic chip testing method.

The automatic chip testing method described in this embodiment is applied to the automatic chip testing system described in Embodiment 1. The automatic chip testing system includes a client and a server connected to the client. The server includes a main board and a chip connected to the main board. The main board and the chip perform intersystem data interaction according to one or more transmission protocols. The transmission protocols are chosen from the SGPI/O protocol, the LPC protocol, the I2C protocol and the SPI protocol.

As shown in FIG. 3, the chip automatic test method specifically includes the following steps:

S31: The client is used to send a test instruction regarding the chip.

In this embodiment, the client is configured with interface connection software for communicating with the server, for example, PuTTY (a connection program for Telnet, SSH, rlogin, pure TCP and serial interface).

Specifically, the test instruction comprises a register instruction, and the format of the register instruction is address bit+register value.

S32: The main board receives the test instruction, converts the test instruction into a test file, and transmits the test file to the chip.

Specifically, the main board at S32 converts the test instruction into a test file conforming to one or more of the SGPI/O protocol, the LPC protocol, the I2C protocol and the SPI protocol.

S33: After receiving the test file, the chip triggers a test item related to the test file, the test item is started, and a functional test result of the chip is generated.

Specifically, the chip in S33 converts the function test result of the chip into a test result conforming to one or more of the SGPI/O protocol, the LPC protocol, the I2C protocol and the SPI protocol.

S34: After the main board receives the converted function test result of the chip, it converts it into a test log file recognizable by the client, and sends the test log file to the client. After receiving the test log file, the test engineer compares the test log file with a reference test SOP to determine whether the test result indicates a success or failure so as to save test time and improve the reliability of the test result.

The execution orders of various steps enumerated in the present disclosure are only examples of the presently disclosed techniques, and are not intended to limit aspects of the presently disclosed disclosure. Any omission or replacement of the steps, and extra steps consistent with the principles of the present disclosure are within the scope of the present disclosure.

The present disclosure also provides an automatic chip testing system, which can implement the automatic chip testing method. The automatic chip testing method can also be implemented by devices not described herein. For the structure of the automatic chip testing system disclosed herein, any structural modification and replacement of the prior art made according to the principles of the present disclosure all falls within the scope of the present disclosure.

In sum, the automatic chip testing system and method described in this application have the following beneficial effects:

First, this application can realize a uniform test mode, and eliminates the need for a test engineer to understand the system, and the test can be simply conducted by referring to the SOP which provides a clear testing process.

Second, this application has high portability, offers modular division of labor, and embeds test modules in working modules to reduce secondary development work;

Third, this application offers automatic and intelligent script testing;

Fourth, this application improves the reliability of test results and reduces human factors by 100%;

Fifth, this application saves test time and is easy to operate;

Sixth, this application has strong applicability and reduces training costs.

While particular elements, embodiments, and applications of the present disclosure have been shown and described, it is understood that the disclosure is not limited thereto because modifications may be made by those skilled in the art, particularly in light of the foregoing teaching. It is therefore contemplated by the appended claims to cover such modifications and incorporate those features which come within the spirit and scope of the disclosure.

What is claimed is:

1. An automatic chip testing system, including:
a client, sending a test instruction regarding a chip; and
a server, including a main board, and a chip connected to the main board,
wherein the main board receives the test instruction, converts the test instruction into a test file, and transmits the test file to the chip,
wherein the chip triggers a test item related to the test file after receiving the test file, generates a function test result of the chip, and sends the function test result of the chip to the client through the main board.

2. The automatic chip testing system according to claim 1, wherein the test instruction comprises a register instruction, and the format of the register instruction is address bit+register value.

3. The automatic chip testing system according to claim 1, wherein
the client sends the test instruction to the main board through a universal asynchronous transceiver or a network interface controller, and the main board sends the function test result of the chip to the client through a universal asynchronous transceiver or a network interface controller.

4. The automatic chip testing system according to claim 1, wherein
the main board and the chip perform intersystem data interaction according to one or more transmission protocols, and the transmission protocols are chosen from the SGPI/O protocol, the LPC protocol, the I2C protocol and the SPI protocol.

5. The automatic chip testing system according to claim 4, wherein a central processing unit, integrated south bridge, substrate management controller, or voltage regulation module of the main board performs data interaction with the chip.

6. The automatic chip testing system according to claim 4, wherein
the main board converts the test instruction into a test file conforming to one or more of the serial general purpose input (SGPI) protocol, the low pin count (LPC) protocol, the Inter-Integrated Circuit (I2C) protocol and the Serial Peripheral Interface (SPI) protocol, and
the chip converts the function test result of the chip into a test result conforming to one or more of the serial general purpose output (SGPO) protocol, the LPC protocol, the I2C protocol and the SPI protocol.

7. The automatic chip testing system according to claim 4, wherein the main board converts the function test result of the chip into a test log file recognizable by the client, and sends the test log file to the client.

8. The automatic chip testing system according to claim 1, wherein the chip includes at least one of a complex programmable logic device and a field-programmable gate array.

9. An automatic chip testing method,
wherein the automatic chip testing method is applied in an automatic chip testing system,
wherein the automatic chip testing system includes a client and a server connected to the client, the server includes a main board and a chip connected to the main board,
wherein the automatic chip testing method includes:
sending, by the client, a test instruction regarding the chip;
receiving, by the main board, the test instruction, converting, by the main board, the test instruction into a test file, and transmitting, by the main board, the test file to the chip;
after receiving the test file, triggering a test item related to the test file, by the chip, to generate a functional test result of the chip; and
sending the function test result of the chip to the client by the main board.

10. The automatic chip testing method according to claim 9, wherein
the main board and the chip perform intersystem data interaction according to one or more transmission protocols, and the transmission protocols are selected from the SGPI/O protocol, the LPC protocol, the I2C protocol and the SPI protocol; and
the converting, by the main board, the test instruction into a test file includes the main board converting the test instruction into a test file in compliance with one or more of the SGPI/O protocol, the LPC protocol, the I2C protocol and the SPI protocol.
